(19) United States
(12) Patent Application Publication
(10) Pub. No.: US 2015/0177423 A1
(43) Pub. Date: Jun. 25, 2015

(54) OPTO TEXTILE

(71) Applicant: Marco SCIPIONI, Charlotte, NC (US)

(72) Inventor: Marco SCIPIONI, Charlotte, NC (US)

(73) Assignee: LUMIA GROUP, Charlotte, NC (US)

(21) Appl. No.: 14/578,559

(22) Filed: Dec. 22, 2014

Related U.S. Application Data
(60) Provisional application No. 61/919,772, filed on Dec. 22, 2013.
(60) Provisional application No. 61/939,407, filed on Feb. 13, 2014.

(51) Int. Cl. G02B 3/00; H01L 31/055; H01L 31/054; G02F 1/01; G02B 5/02

(52) U.S. Cl. CPC G02B 3/00; G02F 1/0147; G02B 5/02; H01L 31/0543; H01L 31/0547; H01L 31/055

(57) ABSTRACT

The opto textiles of the present invention utilize and exploit the light interaction characteristics of the fiber or yarn itself, and the light interaction characteristics of the fabric as a whole, such that the fabric presents a given appearance or provides a given visual effect, adequately cools a wearer/user, adequately heats a wearer/user, and/or fulfills a lifestyle or therapeutic function, for example. In various exemplary embodiments, the present invention provides fibers, yarns, and fabrics that manage and manipulate the properties of light, such as wavelength, propagation direction, degree of coherence, and intensity, utilizing, for example, the light-matter interaction, fluorescence, phosphorescence, photochromism, thermochromism, and heat-activated light generation, such that application-specific needs may be met.

### CROSS-REFERENCE TO RELATED APPLICATION(S)

The present patent application/patent claims the benefit of priority of co-pending U.S. Provisional Patent Application No. 61/919,772, filed on Dec. 22, 2013, and entitled “OPTICAL FABRICS FOR LIGHT THERAPY, COOLING, AND VISUAL EFFECTS,” and U.S. Provisional Patent Application No. 61/939,407, filed on Feb. 13, 2014, and entitled “OPTO TEXTILE,” the contents of both of which are incorporated in full by reference herein.

### FIELD OF THE INVENTION

The present invention relates generally to fibers, yarns, and fabrics that function as a light management platform. More specifically, the present invention relates to fibers, yarns, and fabrics that manage and manipulate the properties of light, such as wavelength, propagation direction, degree of coherence, and intensity, utilizing, for example, the light-matter interaction, fluorescence, phosphorescence, photochromism, thermochromism, and heat-activated light generation, such that application-specific needs may be met.

### BACKGROUND OF THE INVENTION

In many applications, it is desirable that a fabric presents a given appearance or provides a given visual effect, adequately cool a wearer/user, adequately heat a wearer/user, and/or fulfill a lifestyle or therapeutic function. Typically, this is accomplished by controlling the dye of the yarn or fabric as a whole and/or the weave or construction of the fabric as a whole. To date, little attention has been paid to the light interaction characteristics of the fiber or yarn itself, or to the light interaction characteristics of the fabric as a whole. This is the subject of the present invention, which treats a fabric as a substrate consisting of components that actually manage light, such that the fabric as a whole may be used to actually manage light.

### BRIEF SUMMARY OF THE INVENTION

Accordingly, the opto textiles of the present invention utilize and exploit the light interaction characteristics of the fiber or yarn itself, and the light interaction characteristics of the fabric as a whole, such that the fabric presents a given appearance or provides a given visual effect, adequately cools a wearer/user, adequately heats a wearer/user, and/or fulfills a lifestyle or therapeutic function, for example. In various exemplary embodiments, the present invention provides fibers, yarns, and fabrics that manage and manipulate the properties of light, such as wavelength, propagation direction, degree of coherence, and intensity, utilizing, for example, the light-matter interaction, fluorescence, phosphorescence, photochromism, thermochromism, and heat-activated light generation, such that application-specific needs may be met. Thus, the fibers, yarns, and fabrics of the present invention function as a light management platform, treating a fabric as a substrate consisting of components that actually manage light, such that the fabric as a whole may be used to actually manage light. As used herein, “light” is synonymous with “radiation” and includes, for example, visible light, near-infrared (near-IR) radiation, and infrared (IR) radiation, the latter two representing “long-wavelength” radiation. Incident light and reflected light are also used interchangeably.

In various exemplary embodiments, the present invention provides a light management substrate, comprising: a first component having a first predetermined optical property; and a second component having a second predetermined optical property. The first component and the second component each comprise one of a fiber, a yarn, a layer, a coating, and a structural component. It will be readily apparent to those of ordinary skill in the art that the first component and the second component may be the same or they may be different. The first component and the second component are assembled into one of a fabric, a layer, and a planar structure. The first predetermined optical property and the second predetermined optical property each comprise one or more of a scattering property, a fluorescence property, a phosphorescence property, a photochromic property, a thermochromic property, and a filtering property. Optionally, one or more of the first component and the second component scatter incident light. Optionally, one or more of the first component and the second component absorb incident light and fluoresce resulting light. The resulting light may be one or more of visible light, near-infrared light, and infrared light. Optionally, one or more of the first component and the second component is one or more of phosphorescent, photochromic, and thermochromic. Optionally, one or more of the first component and the second component are visually opaque. Optionally, one or more of the first component and the second component are one or more of visually transparent, transparent to near-infrared light, and transparent to infrared light. Optionally, one or more of the first component and the second component comprise a filtering material. Optionally, the filtering material is disposed proximal to a structure disposed adjacent to the substrate. Optionally, the filtering material is disposed distal from a structure disposed adjacent to the substrate. Optionally, the first component and the second component are disposed at least in part in a spaced apart relationship across a width of the substrate. Optionally, the first component and the second component are disposed at least in part in a vertical configuration across a height of the substrate. Optionally, one or more of the first component and the second component act as an optical waveguide. Optionally, at least one of the first component and the second component act as at least a part of a lenticular lens.

### BRIEF DESCRIPTION OF THE DRAWINGS

The present invention is illustrated and described herein with reference to the various drawings, in which like reference numbers are used to denote like structural components/method steps, as appropriate, and in which:

FIG. 1 is a schematic diagram illustrating, in general, the manner in which the fibers, yarns, and fabrics of the present invention manage and manipulate the properties of light, such as wavelength, propagation direction, degree of coherence, and intensity, utilizing, for example, the light-matter interaction, fluorescence, phosphorescence, photochromism, thermochromism, and heat-activated light generation, such that application-specific needs may be met;

FIG. 2 is a schematic diagram illustrating the manner in which an atom or molecule receives incident light and generates scattered light, for example;

FIG. 3 is a schematic diagram illustrating an additive color mixing process;

FIG. 4 is a schematic diagram illustrating the heat conduction rate and temperature gradient between the inner and outer surfaces of a worn fabric;

FIG. 5 is a schematic diagram illustrating a spectral conversion from broad to narrow long wavelength using the opto textiles of the present invention—the long wavelength light is directed towards the interior (body) to increase the heating effect;

FIG. 6 is a schematic diagram illustrating the penetration depth of different wavelengths of light into the human skin;

FIG. 7 is a schematic diagram illustrating an open-weave opto textile of the present invention;

FIG. 8 is a schematic diagram illustrating the functionality of the open-weave opto textile of the present invention;

FIG. 9 is a schematic diagram illustrating an opto fluorescent yarn of the present invention;

FIG. 10 is a schematic diagram illustrating an optical fabric co-woven with two yarns, thereby providing cascading energy removal;

FIG. 11 is a schematic diagram illustrating the sunlight spectrum showing the large portion of solar energy in the IR region of the spectrum;

FIG. 12 is a schematic diagram illustrating an opto fluorescent yarn of the present invention incorporating a filter coating;

FIG. 13 is a schematic diagram illustrating the conversion of broadband sunlight into narrowband long wavelength light to induce heating effects;

FIG. 14 is a schematic diagram illustrating another opto fluorescent yarn of the present invention incorporating a filter coating; and

FIG. 15 is a schematic diagram illustrating an opto therapeutic fabric of the present invention;

### DETAILED DESCRIPTION OF THE INVENTION

Again, the opto textiles of the present invention utilize and exploit the light interaction characteristics of the fiber or yarn itself, and the light interaction characteristics of the fabric as a whole, such that the fabric presents a given appearance or provides a given visual effect, adequately cools a wearer/user, adequately heats a wearer/user, and/or fulfills a lifestyle or therapeutic function, for example. This general functionality is illustrated in FIG. 1, with the fiber, yarn, or fabric 10 providing a visual effect 12, directing heat inwards 14, or directing heat outwards 16, either responsive to incident (or reflected) radiation 18 or otherwise. In various exemplary embodiments, the present invention provides fibers, yarns, and fabrics that manage and manipulate the properties of light, such as wavelength, propagation direction, degree of coherence, and intensity, utilizing, for example, the light-matter interaction, fluorescence, phosphorescence, photochromism, thermochromism, and heat-activated light generation, such that application-specific needs may be met. Thus, the fibers, yarns, and fabrics of the present invention function themselves as a light management platform.

The opto textile technology of the present invention may be implemented in conjunction with other existing special performance textile technologies, like geotextiles, nanotechnology textiles, push/pull fabric constructions, phase change material (PCM) textiles, temperature/humidity gradient textiles, etc., designed for applications like moisture management, waterproofing, comfort cooling, and comfort heating. Functional finishes and coatings for antimicrobial, antistatic, crease-resistance, flame-resistance, water and oil repellency, waterproofing, etc. are all also compatible with the opto textiles of the present invention, providing additional properties without affecting the performance of the optical fabrics themselves.

The design and implementation of opto textiles of the present invention may be in the form of woven (with no weave-pattern limitations), knitted, and nonwoven textiles. Fibers or yarns may be intertwined, interlaced, or intermeshed to form multidimensional structured fabrics. Opto textile fibers or yarns may be extruded using homopolymer, copolymer, or polyblend (homogenous or heterogeneous mixtures of different homopolymers or copolymers) resins. The optical fibers or yarns may also be combined with fibers or yarns of different composition (artificial or natural) to enhance aesthetics, tailor properties for specific needs, or improve fabrication processes. For example, it may be feasible to directly color dye one type of participating yarn in a fabric without affecting the color of another type of participating yarn, such as an optical yarn.

Different yarn typologies are possible, including: monofilament, multifilament, or staple. Opto textiles yarns may result from yarn mixes (mixed colors, mixed deniers, mixed cross-sections, mixed bicomponent/homofilament, etc.) to produce composite yarns with desired properties and aesthetics. Common cross-sections are mono-component and all its variations, bicomponent and all its variations (concentric, eccentric, tipped, hollow, etc.), multicomponent, side-by-side, multi-lobal, segmented cross, tipped, hollow pie wedge, island in the sea, segmented pie structure, etc.

The different forms of electromagnetic radiation are distinguished from each other by their wavelength and energy. The solar radiation (sunlight) that reaches the Earth's surface consists mainly of ultraviolet (UV) (7%), visible (44%), and near-IR (55%). Visible light refers to the portion of the electromagnetic spectrum with wavelengths between about 400 nm and 700 nm that are perceived by the eye. We see objects because of the visible light that they reflect towards our eyes. The eye interprets the different wavelengths of visible light as colors—moving from red, through orange, green, and blue to violet as wavelength decreases. Dark clothing, for example, mostly absorbs energy in the visible range of the spectrum, leading to an increase in body temperature.

UV light is in the 290-380 nm range, while IR light is subdivided into near-IR (780 nm to 3000 nm), intermediate-IR (3000 nm to 6000 nm), far-IR (6000 nm to 15000 nm), and extreme-IR (15000 nm to 1 mm). The human body radiates IR quite weakly, starting at 3000 nm and peaking at about 10000 nm. IR radiation is invisible to the eye, but can be detected as heat.

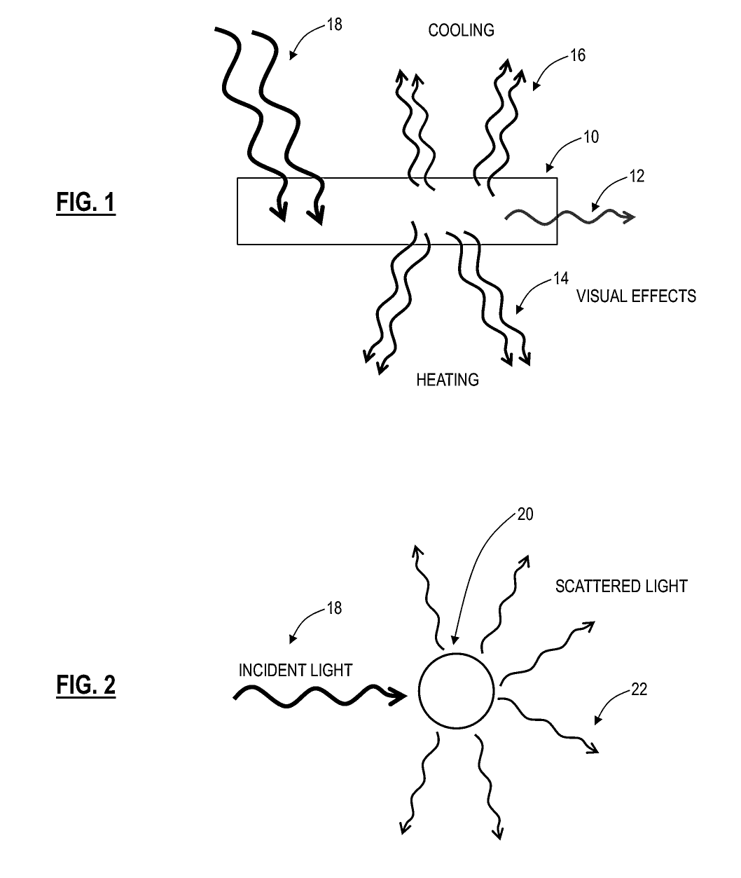

Self-luminous objects generate their own light and act as light sources. Objects that are not self-luminous can only react to the light incident upon them. Referring to FIG. 2, an atom or molecule 20 receives incident (or reflected) light 18 and generates scattered light 22, for example. In general, matter can absorb, reflect, or transmit the incident light (or provide combinations of these processes). When matter is illuminated with energy in the form of light, the molecules can absorb that energy and become excited via electronic transitions if the incident photons have frequencies matching any of the resonance frequencies of the substance. When not absorbed, photons are simply scattered and/or reflected. The process of light reflection is the macroscopic manifestation of scattering occurring at submicroscopic levels.

After absorbing energy, an excited molecule has the option of emitting a photon, but it is often more likely that the absorbed energy will be converted to thermal energy via interactions with neighboring atoms. A process in which an excited atom or molecule is de-excited without radiating is called a non-radiative transition (radiates heat, which is radiation at very long IR wavelengths).

The mechanism responsible for the color of conventional objects is the selective absorption of light in a certain band of wavelengths, followed by non-radiative transitions. The object's color is determined by those wavelengths that are not absorbed, but reflected. Colored objects act like filters that selectively absorb some light and reflect the non-absorbed wavelengths. If all wavelengths are reflected the object is perceived as white if illuminated by a white light. Darker objects in the sun get hotter than lighter objects because they absorb most of the energy present in all wavelengths of the incident radiation with limited reflection.

It is worth noting that the color of an object is determined not only by its chemical molecular composition, but also by the illumination conditions: objects painted red can only appear red if the light falling on them contains sufficient red radiation so that this radiation can be reflected. A red object will in fact appear dark when illuminated with a light source missing the red spectral component in the illuminating radiation. So when we talk about the color of an object, we implicitly assume its perceived color under white sunlight illumination that contains all wavelengths (colors).

Light reflected off the object triggers light sensitive cells in the eye. The cells send a signal to the brain, where the color is perceived. It is possible that the perceived wavelength of light does not necessarily correspond to the spectral distribution of the light reaching our eyes. The colors from ordinary objects are not spectrally pure. Spectroscopic analysis shows that the reflected light can contain bands of wavelengths centered at the specific perceived wavelength or wavelengths that are completely different from the wavelength associated with the perceived color. Therefore, the perceived color of a light reflecting surface is determined by the spectral composition of the light by which it is illuminated, the spectral reflectance characteristics of the surface, as well as the perception of the observer, and as we will discuss next, the emission characteristics.

Fluorescent substances have a chemical composition or physical structures such that part of the absorbed incident energy is not entirely converted into thermal energy as happens in the selective absorption process for conventionally colored objects. Fluorescence is a photon emission process that occurs during relaxation from electronic excited states. This photonic process involves transitions between electronic and vibrational states of polyatomic fluorescent molecules called fluorophores. After being excited, molecules go from the lowest vibrational level of the electronic ground state to an accessible vibrational level of an electronic excited state. These emitted photons have a longer wavelength as compared to the absorbed photons. This shift in wavelength is called Stokes' shift. It is possible for certain fluorescent species to emit radiation with the same wavelength as the absorbed radiation (resonance fluorescence) or even a shorter wavelength due to multi-photon absorption. Fluorescence occurs in nature with minerals and flowers. An interesting example is provided by the gemstone ruby with its very intense red color and sparkle as compared to ordinary red objects.

The intense brightness of fluorescent objects is explainable by the fact that fluorescent substances not only selectively absorb energy at certain wavelengths and reflect energy at other characteristic wavelengths, but also convert part of the absorbed energy into light at a longer wavelength. Fluorescence emission is not restricted to visible light. Some minerals, for example, fluoresce in the IR. The typical glow of daylight fluorescent materials is explained by the efficient absorption of visible light and its conversion into visible light of longer wavelength. It is important to note that the emitted fluorescent radiation always has the same specific wavelength regardless of the excitation wavelength.

Phosphorescence, like fluorescence, is an example of photoluminescence. Phosphorescence happens when an excited molecule passes from an excited triplet state to a lower energy singlet state. This situation is made possible by a mechanism called intersystem crossing that is caused by spin-orbit coupling. The triplet-single conversion and the radiative event have low probability. This means that the molecules will be able to slowly decay back to lower energy states and weakly emit photons. The emission will continue for a very long time after removing the original excitation source. Phosphorescent materials can in fact glow in the dark after the excitation source has been removed. Phosphorescence is a form of delayed fluorescence, therefore it can be viewed as a light capacitor that discharges (gives light away) over a period of time. Because triplet states have lower energy than excited singlet states, the triplet-singlet transition results in the emission of photons having lower energy than the absorbed photons.

Photochromic effects are based on the reversible light-induced conversion amongst two particle types that change the absorption spectrum and consequently their physical properties. Photochromics change from colorless to colored when exposed to sunlight/UV light or to similar sources of light. The color shift appears gradually. The more UV light the paint or the like absorbs, the more bright and intense is its color. When the light decreases, the paint or the like reverts backs to its original structure. This type of material can be used to design and realize dynamic surface patterns at different temperatures, for example.

Thermochromic materials are specialized heat reactive and dynamic substances that change color when exposed to different temperatures. The activation temperature is defined as the temperature above which the substance has almost achieved its final clear color. Below the activation temperature, thermochromic substances are colored and above their activation temperature they are clear or slightly colored. They are usually blended with some other pigments (non-heat sensitive). As they become clear and disappear, one can see the hidden background color. The effect is reversible and occurs instantly. The temperature at which the thermochromic substance changes color can be selected based on the formulation (temperatures range from −15° C. to 60° C.). The temperature change can be caused by a person's breath, holding the object in a hand, putting the object in a pocket, holding the object next to a hot liquid or even in a hot car on a very sunny day, etc.

The two common approaches are based on liquid crystals and leuco dyes. Liquid crystals are used in precision applications, as their responses can be engineered to accurate temperatures, and have a wider color range. Liquid Crystals are generally used for higher precision applications, since the temperature response point can be tightly engineered. Leuco dyes allow a wider range of colors, but their response temperatures are more difficult to set with accuracy. A leuco dye is a dye whose molecules can acquire two forms, one of which is colorless.

The color seen depends on the light source, the colorant used, and the human eye. The two color combination methods commonly used for producing different colors are additive color mixing and subtractive color mixing. The two methods produce very different effects.

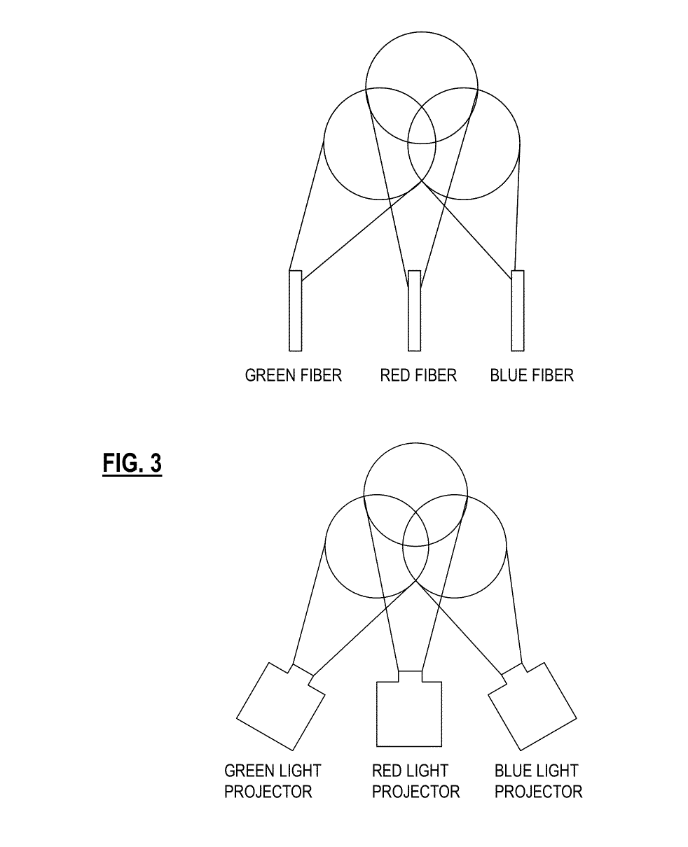

Additive color mixing using the colors red, green, and blue (the additive primaries) is used in computer monitors and television sets, for example. The mixing method is based on the addition of the wavelengths of each light in the mixture. This is illustrated generally in FIG. 3. All spectrally pure light with wavelengths in the visible spectrum can be superimposed to make white light. Interestingly, the perception of white can result from the combination of only red, green and blue light if present in equal quantities. For a particular color, the better defined color corresponds to a narrower spectrum of light at that wavelength, which corresponds to its temporal coherence. The present invention allows for the generation of narrow spectrum light, thereby enabling the generation of very sharp and attractive colors.

The three ways to implement additive mixing are simultaneous optical additive mixing (stage lighting, TV screens, etc.), temporal additive mixing (rotating color wheels or adding high repetition rate light pulses of different wavelengths), and spatial additive mixing. The opto textile technology of the present invention uses simultaneous and/or spatial additive mixing. In spatial additive mixing, due to the limited resolution of the human eye, from a distance, two yarns of different color are perceived as one having the color that is the combination of the colors of the two yarns. Additive color mixing produces desired aesthetics and more luminosity than subtractive (pigment) mixing.

The apparent color of an object can change under different lighting conditions. In certain cases, objects having different spectral distributions look alike under one light source, but appear different when viewed with a dissimilar light source.

A color appearance may be different depending on its relation to adjacent colors (Bezold effect). This optical phenomenon is achieved when small areas of color are interspersed. The opposite effect is observed when large areas of color are placed adjacent to each other, resulting in color contrast. Two or more colors next to each other can create a blending, blurring, or neutralizing effect. For example, blending is achieved when two colors placed next to each other amounts will seem to create their mixture (blue mixed with red can appear violet).

A fabric heat conduction rate is proportional to the temperature difference (gradient) between the inner fabric surface temperature Tᵢₙ and the outer fabric surface temperature Tₒᵤₜ:

ΔT=Tᵢₙ−Tₒᵤₜ

The inner fabric surface temperature Tᵢₙ is approximately equal to the skin temperature T_skin (Tᵢₙ˜Tₛₖᵢₙ) in the case of a worn fabric. The outer fabric surface temperature Tₒᵤₜ is proportional to the air temperature Tₐᵢᵣ and a temperature contribution dT due to sun radiation. This is illustrated generally in FIG. 4.

The opto textile technology of the present invention lowers Tₒᵤₜ by reducing the temperature contribution due to ambient light (such as sunlight). When the air temperature is lower than the inside temperature an increased temperature gradient will be produced, which improves the fabric heat exchange towards the outside environment. When the air temperature is higher than the inside temperature a decreased temperature will be produced, which reduces the heat exchange from outside to inside.

Heat convection is proportional to air flow and provides the important element of breathability (which is the ability to transport moisture from inside clothing to the outside, and air from the outside inward through the clothing). The key to keeping cool in hot weather is to induce evaporation—the more rapid the evaporation, the more effective the cooling. Evaporation is promoted when air flow and air circulation are increased because air convection transports the effect of perspiration away. The opto textile technology of the present invention provides a mechanism for better breathability as will be discussed later.

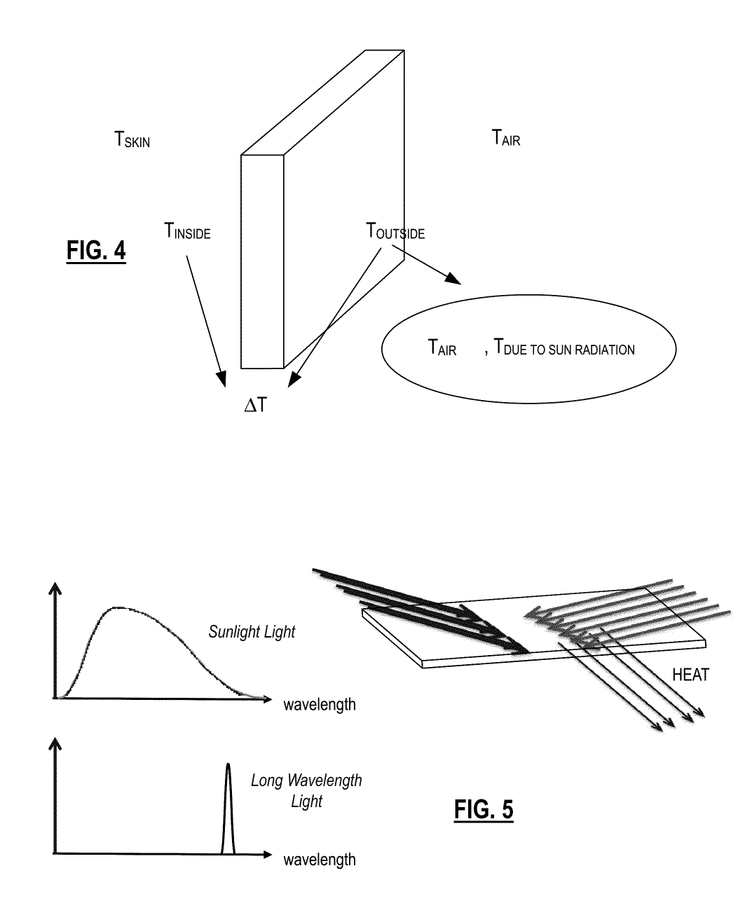

The conversion of the incident sunlight (broad spectrum) into light with a wavelength in the red and near-IR region of the spectrum is the primary working mechanism used by the opto textile technology of the present invention to produce a heating effect, for example. Referring specifically to FIG. 5, the optical yarns 10 act as light tuners and concentrators in the sense that large portion of the incident (or reflected) sunlight 18 is transformed into long wavelength, highly penetrating light 14 that is equivalent to heat. The opto textiles only absorb part of the incident light spectrum, therefore allowing most light to pass through them and create a transparency window that contributes to heat generation.

It is well recognized that light can affect the growth and metabolism of organisms, ranging from simple unicellular microorganisms to multi-cellular plants and mammals, and can produce a variety of beneficial therapeutic effects. Light therapies have moved from the use of direct sunlight to the use of filtered sunlight and artificial light sources. Early applications of light for therapeutic purposes included the treatment of skin diseases and ulcers, syphilis, lupus, pellagra, wound healing, and tuberculosis. These treatments focused largely on the application of light in the UV range of the spectrum. The most recognized physiological effects are photosynthesis in plants and the production of vitamin D in mammals.

Light photomodulation is becoming a more established science with verifiable results, leading to the use of light as a treatment option. Sunlight tans the skin and sets biological rhythms. Visible light is being used as an antidepressant to clinically treat seasonal affective disorder (SAD) (winter depression) and some sleep disorders due to cardidian genes being out of sync. Results identify the 446-477 nm portion of the spectrum as the most effective wavelengths in improving circadian regulation for regulating melatonin secretion. Light has also been introduced as a standard method of treatment for neonatal jaundice. Such effects are mediated by photoreceptors in the eye and involve brain and neuroendocrine organs or through the light-tissue interaction.

The biochemical mechanisms underlying the positive biological effects are still being investigated. The combination of changeable light parameters such as wavelength, power density, pulse structure and treatment timing is complex. Studies identified mitochondrial cytochrome c oxidase as an endogenous photoreceptor for photobiomodulation, but the cellular and molecular mechanisms underlying photobiomodulation are not completely clear. Photobiomodulation uses low energy light, especially in the visible red to near-IR range, to affect the activity of one or more endogenous enzyme photoreceptors. The wavelengths of light used in photomodulation therapy are matched to the absorption spectra of the photosensitive reagent. The visible and IR wavelengths can penetrate tissues and, at the same time, lack the carcinogenic and mutagenic properties of ultraviolet light.

The Grotthuss-Draper law of photobiology states that light must be absorbed by the chemical substance in order for a photochemical reaction to take place. The therapeutic effects arise as a result of the energy absorbed in the tissue. In the visible and near-IR wavelength ranges, the absorption in tissue is dominated by hemoglobin and melanin, while in the UV spectral range by DNA and proteins.

The Bunsen-Roscoe (Reciprocity) law states that the quantity of the reaction products of a photochemical reaction is proportional to the product of light irradiance and exposure time. Most photobiological effects are cumulative. Research has shown that positive results depend on the administered dose of light, rather than the intensity alone. The same dose (and same effect) can be provided by a high intensity in a short time or a low intensity in a long time. Common light sources used in light therapy typically deliver 10 mW to 500 mW with a power density ranging from 0.005 W/cm² up to 5 W/cm².

An action spectrum provides the relative efficacy of light at certain wavelengths to achieve a specific biological response. All wavelengths are not equally effective at promoting good therapeutic effects and the most effective ones constitute the action spectrum. The spectral response depends on the chromophores required to mediate the energy conversion process. Certain wavelengths of light may be beneficial or essential to human health at one dosage, toxic or destructive at a higher dosage. An action spectrum should mimic the absorption spectrum of the molecules that are absorbing the light. This indicates that the wavelengths that are strongly absorbed can also trigger a photobiological response. Light can either turn on or turn off a chemical reaction by turning a signaling pathway on or off.

Experimental evidence shows that visible light can affect the human immune system response through the skin. Skin is naturally exposed to light more than other organs and responds well to red and near-infrared wavelengths. Visible light can penetrate epidermal and dermal layers to a depth of 2-3 mm and directly interact with circulating lymphocytes to modulate immune system function. Mitochondria are thought to be the main site for the initial effects of light and specifically cytochrome c oxidase that has absorption peaks in the red and near-IR regions of the electromagnetic spectrum. The discovery that cells employ nitric oxide (NO) synthesized in the mitochondria by neuronal nitric oxide synthase, to regulate respiration by competitive binding to the oxygen binding of cytochrome c oxidase, suggests how light therapy can affect cell metabolism.

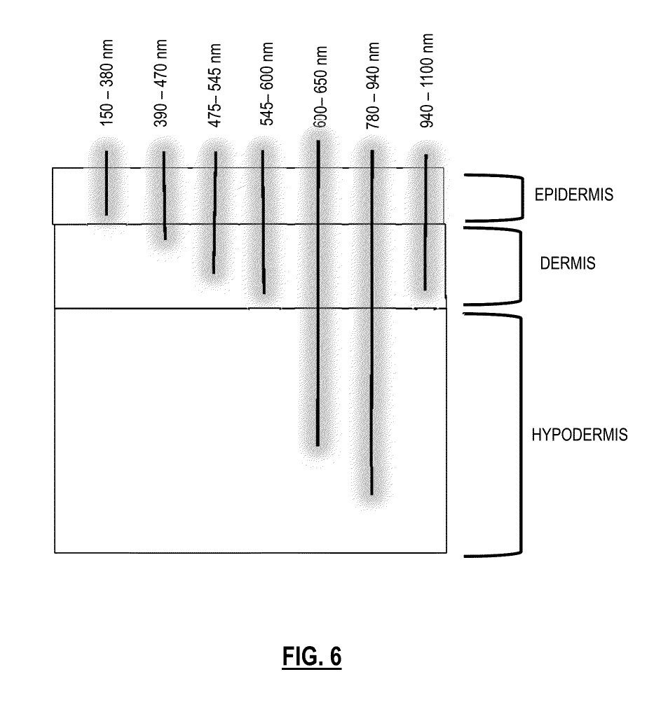

FIG. 6 illustrates the penetration depth of different wavelengths of light into the human skin. Optically, the skin can be regarded as an inhomogeneous medium consisting of three layers: the epidermis, the dermis, and the subcutis (hypodermis). These layers have different refractive indices and distributions of chromophores, hence different scattering and transmission characteristics. Light depth of penetration is contingent on tissue type, pigmentation, and foreign substances on the skin surface. The degree of reflection is also dependent on the melanin content: the darker the skin, the less radiation will be reflected, especially in the visible range.

Visible light in blue-green (475-545 nm) can penetrate twice as far as UV light in the 150-380 nm range, while IR light in the 600-650 nm range can penetrate ten times more deeply than UV light. Light with a wavelength between 600 nm and 1200 nm constitutes the so-called therapeutic window because these wavelengths can penetrate into the subcutis without significant absorption by water.

Opto textile technologies described in this patent focus on the use of visible and IR light for therapeutic purposes, for example.

Visible light can penetrate epidermal and dermal layers and directly interact with circulating lymphocytes to modulate the immune function resulting in enhanced phagocity activity of monocytes and granulocytes and induce proliferation of other human cells. Visible light is the most powerful external regulator of the circadian response. Visible light therapy can quickly rebalance circadian rhythm and speed recovery from jet lag and seasonal depression.

In 1990, NASA developed LEDs as part of a project to grow plants inside the US space shuttle. The plants exposed to near-IR LEDs grew 150 to 200% faster than ground controlled cells not stimulated by these wavelengths. These same near-infrared light (730 nm) LEDs stimulated the growth of cultured skin, bone, and muscle.

IR light has been used for a variety of applications ranging from heating, wound healing, treatment of mouth-sores caused by radiation and chemotherapy, hair regrowth, recovery from cosmetic surgery, joint and soft tissue injuries, arthritis, carpal tunnel syndrome, etc. Very exciting is the potential use of red LEDs to stimulate the regrowth of nerve cells. IR light helps with blood circulation and natural healing by stimulating DNA synthesis in human peripheral blood lymphocytes, but also induces a change in the cytokine content in the blood. IR light penetrates skin cells and forces our nitric oxide and stimulates antioxidants. This reduces cellular stress and increase cellular energy (ATP).

The long IR wavelengths allow for deeper tissue penetration than visible wavelengths: near infrared light (600-800 nm) can penetrate the skin for up to 23 cm and transcutaneously deliver deep into inner tissues such as muscles and nerves. Both visible and infrared radiation penetrate the circulating blood. Light therapy has been using LEDs and lasers as sources of IR radiation. These sources do not allow for the treatment of large body areas and it is technically difficult to use lasers to treat large wounds, among other disadvantages.

Light therapy has been shown to have a wide range of effects at the molecular, cellular, psychosomatic, psychological, and tissue levels. Low energy light therapy is becoming a recognized treatment option for prevention, therapy, and rehabilitation. Common applications are heating, wound healing, pain management, inflammation and restoration of function, treatment of skin disease and skin rejuvenation, hair loss and hair regrowth, chronic ulcers, and chronic pain syndromes like headaches, dermatology (low-level light therapy was approved by the Food and Drug Administration in 2007 for the treatment of mild to moderate male pattern hair loss), acne therapy, photorejuvination (to reverse the process of sun induced aging and environmental damage to the skin), as illustrated in Table 1.

TABLE 1
Wavelengths Used in Various Light Therapy Applications

| Application | Wavelength |
|---|---|
| Cellulite | 660 nm, 950 nm |
| Weight Loss | 635 nm-680 nm |
| Acne | 405 nm |
| Acupuncture | 630 nm |
| Circadian rhythm | 446-477 nm |
| Hair Growth | 635 nm |
| Sleep pattern | 446-477 nm |
| Skin Rejuvination | 532 nm, 1064 nm |
| Vasodilation | 310 nm |
| Pain | 632 nm, 808 nm, 810 nm, 900 nm |
| Sport injuries | 808 nm, 810 nm |
| Muscle Relaxation | 808 nm, 810 nm |
| Cartilage growth | 900 nm, 1064 nm |
| Vitamin D | 280 nm-320 nm |
| Blood flow | 310 nm, 410-420 nm, 540-550 nm, 570-580 nm |
| Bone regeneration | 830 nm |

In general, a time varying irradiation appears to be preferable for optimal results because the variable irradiation may avoid biological adaptation that will quench the efficacy. Low energy light therapy is becoming a recognized treatment option for prevention therapy and rehabilitation.

Thus, the opto textile technologies of the present invention may be applied in the following:

Comfort Cooling Fabrics
Perforated Optical Fabric
“Cool” Optical Fabric
“Cool” Optical Fabric with Thermochromics and Photochromics
“Cool” Optical Fabric with Energy Blocking Filter

Comfort Heating Fabrics
Thermal Optical Fabric (fluorescence +thermal insulation)
Optically Perforated Fabric (improved radiation heating)
Thermal Optical Fabric with Energy Trapping Filter

Therapeutic Fabrics
Therapeutic Optical Fabric

Visual Effects Fabrics
Optical Decorations
Optical Lighting
Hyper-Colored Optical Fabric
Hollow Microsphere Fabric
Lenticular Optical Fabric

Optically Masking Fabrics
“Photo” Optical Fabric
Thermo-Transparent Optical Fabric

Opto textile technologies are based on the principles of fluorescence, phosphorescence, thermochromics, and photochromics, for example.

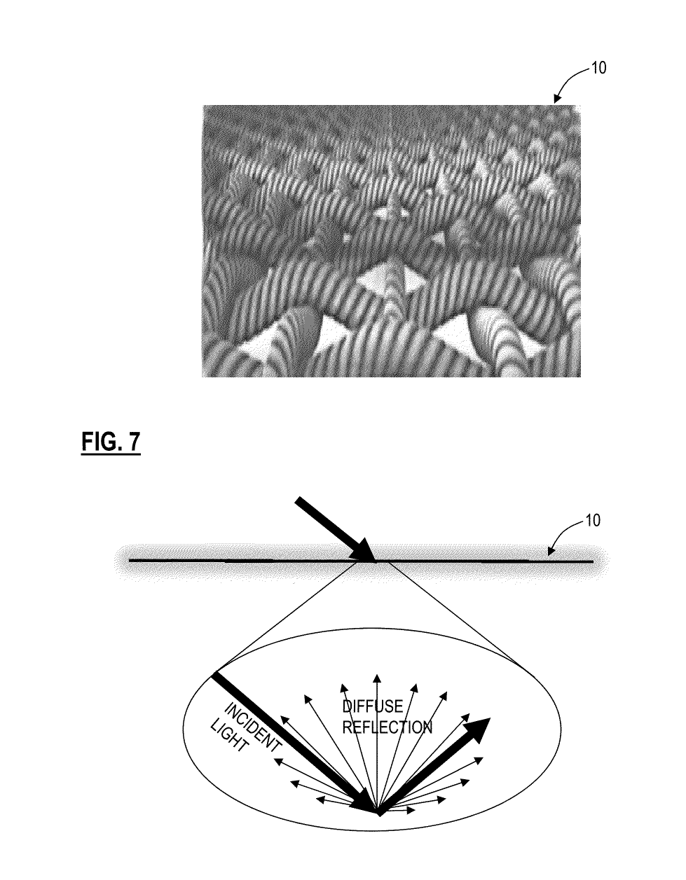

Perforated optical fabrics are composed of fluorescent yarns arranged in an open-weave pattern (it is also applicable to knitted fabrics and non-woven fabrics.) This design has a twofold effect. Increased ventilation is provided through a more open weave pattern (as compared to conventional fabrics) with larger space between the interlaced yarns makes the fabric more breathable and lets more ambient light reach the skin. It is important to note that more ambient light reaches to the skin, while the exposure of skin to outside observer does not increase as it is described next. Perforated optical fabric is woven with opto fluorescent yarns, with each point on a fluorescent yarn acting as a scattering center for light. FIG. 7 illustrates a segment of a red yarn with a yellow (sun) light ray 18 hitting a particular yarn (or component) in the fabric (or substrate) 10. Although high transparency is derived from the open weave structure opto fluorescent fabric, optical concealment is still provided for two reasons: (1) the yarns are highly fluorescent and strongly scatter light into the empty space between the yarns giving an observer the impression of a solid and tightly woven fabric—the light scattered from the fabric surface becomes the primary scattered light that the observer's eye visually sees making the subject behind the fabric not visible; and (2) a conventional transparent fabric allows the skin and body shapes of a subject behind the fabric to be seen—the transparency is explained by the fact that part of the incident sunlight is first transmitted undisturbed through the fabric, then reflected off the human skin—this reflected light passes once again through the fabric to finally reach the observer's eye—it is the light reflected off the skin and exiting through the fabric that carries information about the subject shape.

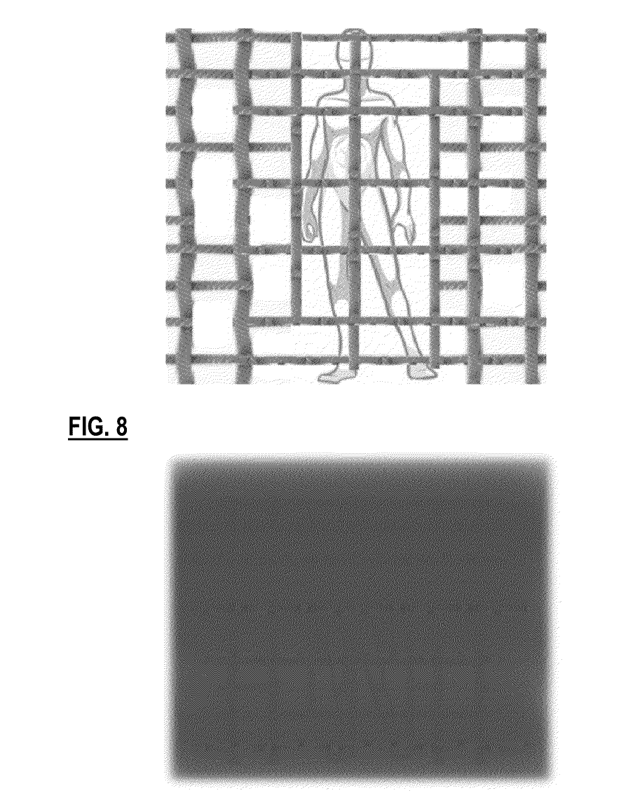

In the case of opto fluorescent fabric, the light reflected off the skin becomes partially absorbed and emitted by the fluorescent fabric on its way out to the observer's eye. This emitted fluorescent light is spectrally and structurally different in comparison to the skin-reflected light. This optical scrambling effect projects a solid fabric surface versus fabric with such an open weave and no fluorescent yarns. This is illustrated generally in FIG. 8.

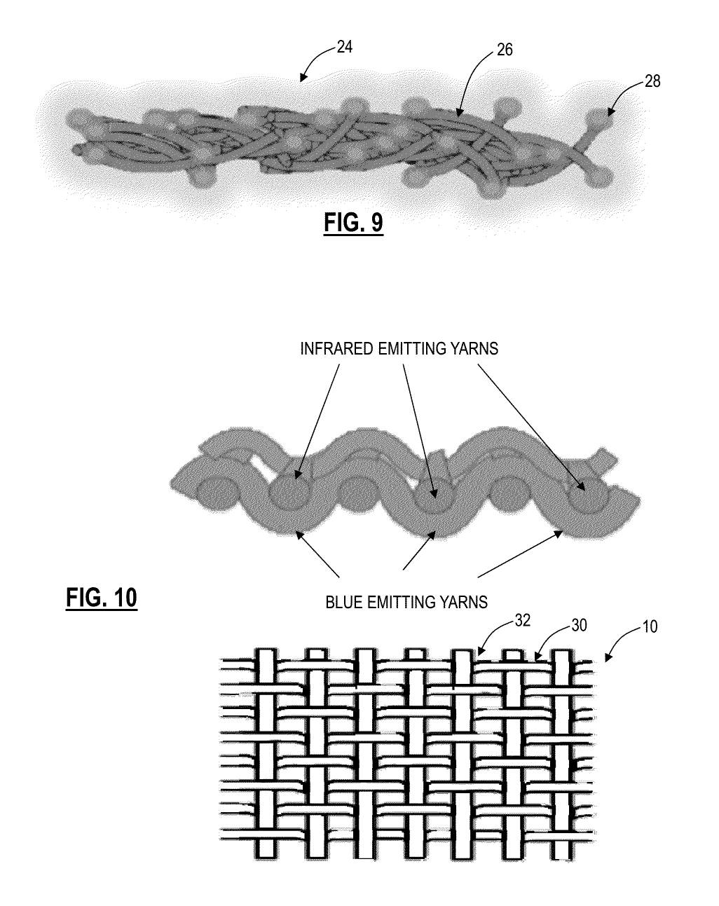

Referring specifically to FIG. 9, opto fluorescent yarns 24 may have a staple yarn design that allows for extra brightness and glow. Each staple fiber 26 has a finite length and acts like a small light waveguide: the staple fiber 26 captures the incident light and guides it to its edges 28 where a noticeable sparkle can be seen. The cumulative effect from each staple fiber 26 makes the whole yarn 28 intensely bright. In order to increase the wave-guiding effect and consequent sparkle at the staple's ends, opto staple yarn can be made in the single component form (one layer, core only), bicomponent form (two layers, core and sheath), and multicomponent (more than 2 layers).

Similar effect can be achieved using multifilament yarns and with proper texturing styles that produce excess scattering. By introducing and combining fluorescent fibers with different color into the fabric, it is possible to adjust the overall fabric color and create interesting visual effects. This color flexibility is based on the principle of additive color mixing described above. One can also use the combined additive and subtractive color generation. Perforated optical fabrics can be very helpful for regenerative medicine and wound-healing since the fabrics can allow for good sunlight exposure of large areas of the body (as compared to local spot treatment) while taking advantage of the beneficial health effects of sunlight and maintaining sufficient coverage for protection and privacy.

“Cool” Optical Fabric is made with fluorescent yarns. Fluorescence is the basic cooling mechanism: a portion of the incident energy is absorbed and re-emitted by the yarns instead of being converted directly into heat. Part of the emitted fluorescent light is emitted back towards the outside environment and part towards the skin. Pigmented yarns, instead, absorb most of the incident energy and convert it into heat while only reflecting a small portion of the incident light at a specific wavelength.

If the optical fabric is woven with fluorescent yarns of different colors (which means different Stokes emission wavelengths) it is possible to enhance the cooling effect in the following way: the energy emitted by one type of fluorescent yarn has the frequency content that can be fully absorbed by the other type of fluorescent yarn.

For example, FIG. 10 shows an optical fabric 10 co-woven with two yarns, one yarn (or component) 30 emitting light in the visible spectrum and one infrared emitting fluorescent yarn (or component) 32. The visible fluorescent yarns 30 absorb incident visible light and emit visible light (for example, blue) in two opposite directions, outward and away from the fabric (hence removing some energy that would otherwise reach the skin) and inwardly toward the skin. The energy that is moving inward toward the skin gets intercepted by the second type of fluorescent fiber 32 and absorbed. The second type fluorescent fiber 32 emits infrared radiation in two directions as well, away from the skin and toward the skin.

This technique could be applied to any number of co-woven yarns (one or multiple yarns) and could be repeated multiple times in a single fabric. The different fluorescent fibers absorb and remove each other's emitted light and re-direct it away from the skin. Each yarn type removes some of the energy emitted by the other fluorescent yarns. This energy removal process can be described as an energy cascade removal. The incident light is gradually attenuated as it travels towards the skin. Most of the incident light gets rejected towards the outside.

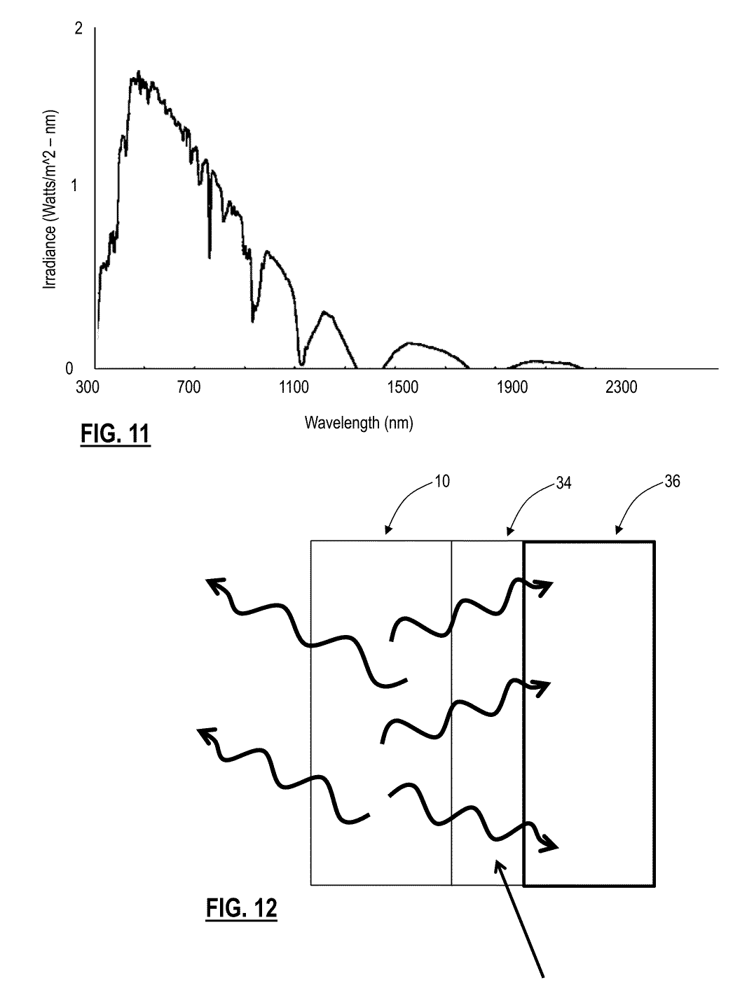

A distinctive and unique feature of the optical fabrics that are designed for comfort cooling applications is that the high efficiency fluorescent dyes in the fabric can be tuned in such a way to make the optical fabric completely transparent to long wavelength IR radiation. About 53% of sunlight radiation (wavelength>700 nm) is infrared (see FIG. 11). The optical fabric can be made transparent to energy contained at those IR wavelengths. That energy would otherwise get absorbed and be converted into heat.

The color black is a very popular and fashionable color in the textile world. It is well known that conventional black, achieved through pigment or dye coloration, has the drawback of becoming extremely hot due to absorption of most of the incident light. This is especially detrimental when cooling (either of the body or of an interior space) is the desired effect. Black colored textiles can be made using opto fluorescent yarns that contain nanoparticles with absorption in the visible spectrum and fluorescent emission in the IR region. These optical fabrics will appear visually black (the human eye is not sensitive to IR) while being cooler than traditional black textiles because of the low light-to-heat conversion that characterizes high efficiency fluorescent nanoparticles.

Thermochromic and photochromic yarns can be co-woven with fluorescent yarns to obtain the following result: the light emitted by thermochromic and photochromic yarns can be eventually absorbed by fluorescent yarns with the suitable absorption spectrum. At that point part, of the light emitted by the fluorescent yarns would be directed towards the outside environment and provide increased cooling. The thermochromic and photochromic yarns can remove external energy autonomously or assist the fluorescent yarns in the energy removal process. The optical processes of thermochromic and photochromic can be used independently or combined to make optical yarns that intrinsically remove energy from the body. The energy removal takes place because the newly generated light that thermochromic and photochromic yarns emit requires the absorption of energy.

Referring to FIG. 12, a coating filter 34 may be applied to the internal side of the “cool” optical fabric 10, facing the skin 36. The coating 34 acts as a filter blocking light generated by the fluorescent yarns, preventing it from reaching the skin 36. This translates into increased coolness (less light reaching the skin 36).

In some applications, it is possible to use highly reflective liners as reflective filters. However, the liners will not be visible to the viewer.

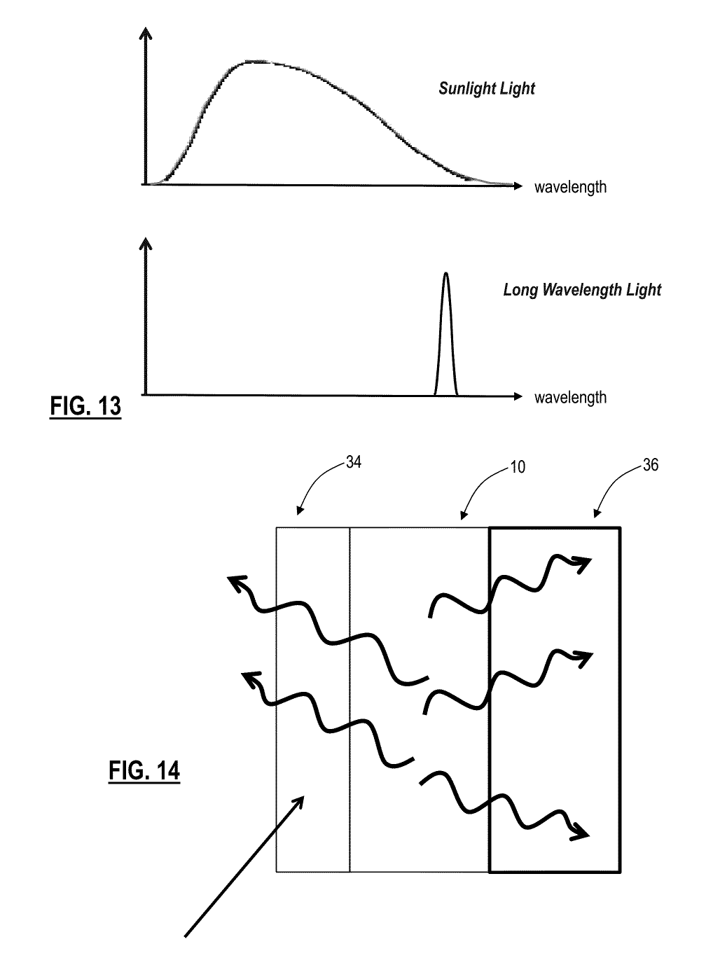

Referring specifically to FIG. 13, the conversion of the incident sunlight (broad spectrum) into light with wavelength in the red and near IR region of the spectrum is illustrated. The optical yarns act as light tuners and concentrators in the sense that a large portion of the incident sunlight is transformed into long wavelength, highly penetrating light that is equivalent to heat.

Radiation is the best way to gain and lose heat. Optically perforated fabric is a regular weave fabric using either only fluorescent yarns or transparent yarns in conjunction with fluorescent yarns. The optically transparent yarns let sunlight radiation reach the skin, taking advantage of radiation heating while insulating against cold weather. The fluorescent yarns can also be designed to allow most of the incident light to pass through.

The highly fluorescent yarns strongly scatter light obviating the transparency contributed by the clear yarn and giving an observer the impression of a solid colored fabric.

Referring specifically to FIG. 14, a coating filter 34 is applied to the external side of the thermal optical fabric, facing the outside environment side. This blocks the energy generated by the fluorescent yarns preventing it from escaping to the outside (heat trapping). This translates into increased warmness.

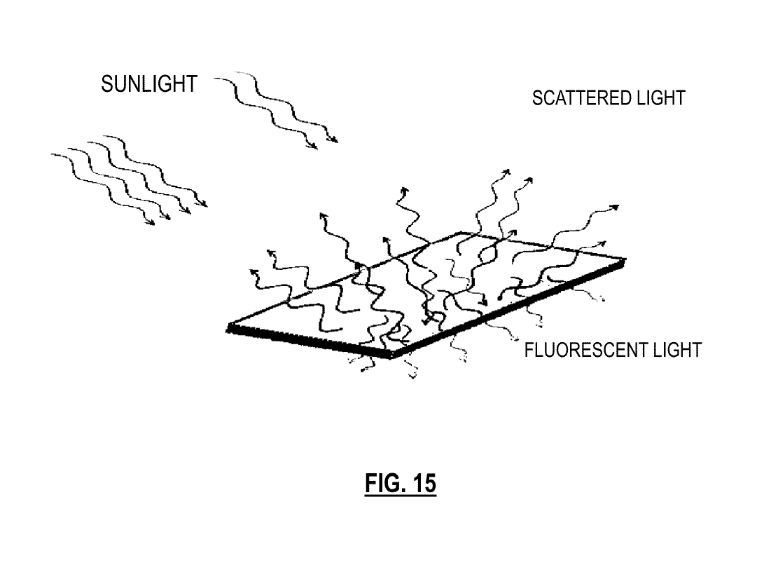

Referring specifically to FIG. 15, opto therapeutic fabric 40 is made with yarns that have been embedded with fluorescent nanoparticles (dyes and/or quantum dots) having given properties depending on the application. The nanoparticles are designed to emit light at visible or near-IR wavelengths. The nanoparticles transform part of the wideband incident ambient light into narrowband light with the precise wavelength that studies have shown to have beneficial therapeutic effects for hair regrowth, weight loss, muscle toning, skin rejuvenation, and several other treatments, for example.

Opto therapeutic fabrics have several useful attributes and features:
Active Fabric: Opto therapeutic fluorescent fabric is active and can enable any type of garment to provide health benefits and treat specified conditions.
Protective Fabric: Opto therapeutic fabric can be designed to offer extra protection against those wavelengths having damaging effect on the human skin. The protective mechanism is accomplished by converting the energy in those spectral regions into energy at more useful and helpful wavelengths.
Integration: Opto therapeutic fabrics may be used for the entire garment or only on specified areas.
Non-Invasive: Opto therapeutic fabric is a non-invasive treatment, an alternative to medication that can aid the body heal naturally.
Variable Irradiance: Natural movement combined while wearing opto therapeutic fluorescent fabric can offer a similar type of modulation (and the associated benefits) that a source like a laser, LED, or lamp with pulsating irradiance offers.
High Exposure Time: The time exposure to light with a beneficial wavelength while wearing opto fabrics may be much longer than the typical time exposure involved in conventional light therapy treatments using LEDs and laser sources. Since the time of exposure can be long the light intensity does not need to be high to provide an effective light dosage.
Area Coverage: Opto therapeutic fabric can cover a larger area of the body compared to conventional light therapy approaches (which are mostly local).
Ease of Use: Opto therapeutic fabric does not involve repetitive in-office treatments. Opto therapeutic fabric simply needs to be worn during outdoor activities in sunlight.

Fitness and outdoor sportswear can be infused with opto therapeutic fluorescent fabric technology to trigger weight loss and fat reduction. The fabrics can generate light of the appropriate wavelength that has shown to be effective in fat reduction. Opto fabric can be applied to shirts, pants, arm warmers, gloves, sports bras, and athletic and non-athletic clothing in general.

Compared to the conventional, costly, and possibly uncomfortable in-office light therapy sessions for weight loss, opto textile technology is inconspicuous, and can be comfortably worn while being outside.

Opto therapeutic fluorescent fabrics can be incorporated into fitness headwear like hats, caps, etc. to stimulate hair growth. For example, a hat incorporating opto technology can irradiate the scalp with light of the appropriate wavelength and help stimulate hair follicles, promote hair growth, and stop the progression of hair loss.

Light therapy is a painless and non-toxic option that has been FDA approved for the treatment of hair loss. Recent studies have concluded that 93% of the subjects that underwent light therapy for hair regrowth had a real increase in the number of terminal thick hairs.

Opto therapeutic fabrics can be designed to effectively convert most of the incident sunlight into infrared energy to keep muscles warm before and during any fitness or outdoor activity to prevent muscle strain and fatigue. Opto textile technology can be integrated into compression sportswear like shorts, tights, armbands, and wristbands to achieve a greater beneficial effect.

It is possible to combine together the various opto textile technologies in the same garment. Different body parts covered by the same garment may be exposed and targeted by different light wavelengths.

As discussed above, different colors can be generated using either the additive or subtractive mixing method. There are numerous festivals and light celebrations around the world in which lights are used to adorn streets, signage, etc. In part due to advances in the field of LEDs (light emitting diodes), most of the light decorations use LEDs. There is a recent trend in which the manipulation of colored light based on additive color mixing is used to create interesting, flashing, sweeping, and choreographed color visual effects for outdoor and indoor holiday decorations, for the entertainment industry (theatrical costumes, fabrics, stage effects), for logos, etc. Many of these light decorations and applications could be done more elegantly and easily using opto fluorescent and phosphorescent fabric technology. For instance, a decorative light lantern could use a combination of fluorescent and phosphorescent opto fabrics and a single or few LEDs. The light emitted by the LEDs would excite opto fabric and make it fluoresce and emit an intense, bright color. Opto fabrics' technical approach mimics the presence of multiple LEDs and has the potential of creating novel and iridescent color effects. Opto fabrics can be grouped together in specific configurations to produce interesting designs and graphics.

Co-weaving phosphorescent and fluorescent yarns together to provide tents, lamps, etc. with automatic low-level lighting at nighttime or emergency light backup is also possible.

Hyper-colored optical fabric employs the principle of additive color mixing and makes fibers become light sources: fluorescent fibers of different colors emit their own light which overlap to create the effect. The co-woven yarns can be fluorescent, phosphorescent, thermochromic, or photochromic. This translates into original and exciting color effects for logos, garments, portions of garments, etc.

The yarns of the present invention can come in the form of monofilament, multi-layer, and staple yarns. These different types of yarn can be surface texturized to achieve different levels of sparkle and scattering, for example.

Hollow microspheres can be embedded inside the polymer matrix to extrude a new class of opto yarns. Each individual microsphere is an optically transparent scatter of the light from the environment. The overall bulk scattering from multiple spheres make the optical fabrics appear visually white in coloration, for example.

By enhancing light scattering inside the fabric, the hollow microspheres produce less absorption and less heat generation since portion of the incident light is allowed to pass through the fabric. Consequently, more light from the outside environment can enter an interior space making it warmer and more luminous compared to using conventional white textiles while maintaining the necessary level of privacy, in the case of curtains, for example.

Lenticular technology is based on the following optical principle: two or more images are interlaced and covered with an array of transparent lenslets that typically have semi-cylindrical shape. Each semi-cylindrical lens covers two (or more) interlaced stripes. An observer can only sharply focus on one of the interlaced pictures at a time, depending on his/her relative position. When the observer moves with respect to the lenticular image, the observers notices distinct color changes because a different interlaced image is brought more strongly to his visual attention. Several methods exist to realize the lenticular effect. For instance, printing over textiles or the application of semi-rigid, bendable plastic stripes over the textile are well known methods.

Opto lenticular fabric introduces a novel approach for transferring the lenticular effect onto fabrics directly at the yarn level. Fluorescent and transparent yarns are co-woven into a multilayered fabric. The weaving pattern is suitably chosen so that the transparent yarns are mostly on the external face of the fabric. The clear yarns have specific cross-section and diameter for them to cover two or more of the underlying colored fluorescent yarns. The clear yarns acts as lenslets that focus the fluorescent light emitted by the underlying yarns based on the observer's view angle and height. Images or color patterns can be encoded at the yarn level and turned more dynamic by popping in and out of the observer's attention.

The Opto lenticular fabric can significantly impact design visualization by creating eye-catching visual effects or even safety effects that would enhance visibility. It is well known that the human eye responds well to moving and flashing objects.

“Photo” Optical Fabric can be applied on top of solar cells with no or minimal impact on PV performance. The optical fabric converts sunlight into NIR wavelength light (or part of sun spectrum to longer wavelength) increasing solar cells' efficiency (wavelength conversion). This fabric technology can to apply to all PV technology in an aesthetically pleasing and invisible way. An interesting application could be roofing shingles.

The thermo-transparent optical fabric allows accessories, devices, and sensors integrated and hidden inside garments to become visible whenever the user decides to access them. Thermo-transparent optical fabric is a thermochromic-based fabric that becomes transparent upon human touch (heat), letting the device under the fabric become visible. New fashionable and stylish device integration solutions with no visual impact are possible.

By way of enablement, a polymeric host component such as PET, Nylon, acrylic, polyolefin, polystyrene, ABS, polycarbonate, etc. that has optical properties to absorb incident light minimally, reflect a portion of the incident light and emit a large portion of the absorbed light in the form of light with a new wavelength (fluorescence) instead of converting it into thermal energy is used.

Florescence nanoparticles will be added preferably by mixing with the polymeric host material during compounding. It is also possible to mix the fluorescent nanoparticles with the polymer material directly during the extrusion phase of the yarn. It is also possible to dye either the yarn or the fabric after it has been manufactured. However, control on the nanoparticles percentage and concentration is better accomplished via compounding as to date. The typical intrinsic viscosity range for the polymeric host is 0.5-0.8 dL/gram.

The principles and processes described above are applied not only to fluorescent nanoparticles but also to phosphorescent, thermochromic and photochromic nanoparticles mixed with the polymeric host component.

In most applications the fluorescent nanoparticles are selected based on their absorption and emission spectra. The emitted fluorescent light wavelength is tuned to target specific effects.

A filter can be applied to the fabric to reflect and re-direct a portion of the light emitted by the yarns forward or backward toward the object behind the fabric creating cooling or heating effect. The presence of the filter serves to enhance the targeted effect.

The principal method of extrusion is melt spinning: resin solids are melted. The fiber is spun into the air and solidifies on cooling. It is the least expensive spinning method. T he fibers are shaped like the spinneret holes.

The fluorescent particles are compounded into pellets made of highly transparent polymer that are later extruded into fibers of different types and cross-sections. Particles concentration used: ˜0.01%-5% (depends on color and yarn type).

Sample fluorescent products that may be used include:
Suppliers: Exciton, DayGlo
Material Form: Powder
Composition (Exciton): proprietary information
Composition (DayGlo): Perylene, Coumarin, Thio-xanthene, thiophene, stilbene, anthrax-quinone
Color: multiple colors
Particle size range (micron):
(Choice depends on desired brightness, yarn structure and denier)
Quantum efficiency: 0.4-0.9 (depends on the application)
Emission wavelengths: visible and infrared

The phosphorescent additives are pigments. They maintain their original shape and they do not color the medium around them. Larger particles, within a grade, are brighter. However, larger particle sizes create rough textured surfaces. On thin applications, they can also create a speckled look when observed closely. Smaller particle sizes look and feel smoother at the cost of brightness. The phosphorescent particles are compounded into pellets made of highly transparent polymer (low TiO2) that are later extruded into fibers of different types and cross-sections. Particles concentration used: ˜10%

Sample phosphorescent products that may be used include:
Company: Glowinc
Product name: Ultra Green V-10
Material Form: Powder
Composition: The raw glow pigment is Alkaline Rare Earth Metal Silicate-Aluminate
Oxide Europium Doped.
Coated: Coated Pigments have a thin protective layer added to each individual particle. This prevents them from dissolving in water or being damaged by some acids. They are also more durable.
Glow Color: Green-Yellow
Daytime Color: Very Light Green
Particle size range (micron): 35-65 or 10-20 (Choice depends on desired brightness, yarn structure and denier)
Brightness range (mcd/m̂2): 945 to 126

Thermochromic pigments are microcapsules in a powder form. They reversibly change color with temperature. They are colored below their set activation temperature and change to colorless or to another lighter color as they are heated through the temperature range. They are available in various colors and activation temperatures.

Activation temperature: the activation temperature can be set anywhere between 10 C and 69 C. It is defined as the temperature above which the pigment has almost (>95%) achieved its final clear or light color end point. Reversible temperature reactive pigments may be used. The thermochromic particles are mixed with polymeric materials and compounded into pellets made of highly transparent polymer that are later extruded into fibers of different types and cross-sections.

Sample thermochromic products that may be used include:
Company: QCR Solutions
Material Form: Powder
Composition:
Color: Black, red, magenta, blue, green, orange, purple. Custom matching is available.
Particle size range (micron): <6 micron (97%)
Shelf Life: 12 months
Light Fastness: 1-2

Photochromic dyes are reversible raw dyes in crystalline powder form. They change color upon exposure to ultraviolet light in the range of 300 to 360 nm. The dyes change back to colorless when removed from the UV light source. Photochromic dyes are compatible with one another and can be mixed together to provide a wider range of colors. Photochromic pigments are photochromic microcapsules in a powder pigment form. They will respond to natural sunlight as well as artificial sources of 365 nm “black light”. The photochromic particles are compounded into pellets made of highly transparent polymer that are later extruded into fibers of different types and cross-sections. Particles concentration used: depends on the application

Sample photochromic products that may be used include:
Company: QCR Solutions
Material Form: Powder
Composition: Formaldehyde and Isopropylidenediphenol
Dye Colors: Blue, green, orange, red, yellow
Pigments Colors: Blue (PMS 2995U), magenta (PMS 2405U), orange (PMS 1495U), green (PMS 3268U), purple (254U), red (PMS 1797U) and yellow (PMS 116U).
Particle size range (micron): <7 micron (97%)

Each individual yarn can be manufactured to contain the fluorescent, phosphorescent, thermochromic and photochromic additives separately.

The bicomponent yarn form is also possible. The fluorescent, phosphorescent, thermochromic and photochromic additives would separately reside inside the core of each different bicomponent fiber while the sheath, made of a transparent polymer, completely would surround the core. The presence of the sheath layer provides increased strength and represents a safety improvement by reducing the possibility of contamination from traces of the additives accidentally getting into contact with the patient.

The clear sheath layer is extremely important in the case of phosphorescent yarns or in the case of high concentration usage. For example, very bright phosphorescent particles tend to be large in size and compromise the integrity of the fiber itself If the desired additive concentration is high the entire yarn consistency would end up depending on the additive material instead of on the host polymer. In both cases, the clear protective sheath layer helps conserve the yarn physical integrity.

Beside the transparent sheath design, other feasible bicomponent variations and all its permutations are possible. For example, the core contains the phosphorescent additive and the sheath contains the fluorescent additive. In the different situation, the core contains the thermochromic additive and the sheath contains the fluorescent additive, etc.

Aside from the core-sheath design, the bicomponent yarns can be realized in the following variations:
Bilateral (side-side)
Island in the sea
Pie chart
Asymmetric core-sheath

Multi-component yarn is another example of physical mixing: different sections of the same yarn contain different additives (either fluorescent, phosphorescent, photochromic or photochromic). The additive concentration, length, and color can vary from section to section. This type of yarn can be manufactured using multiple hoppers loaded with compounded pellets containing different additives. The various hoppers would alternatively feed, in a round robin fashion, the same extruder to manufacture the segmented yarn.

Each individual fluorescent, phosphorescent, thermochromic and photochromic yarn can have the following cross-sectional shapes:
Circular
Oval
Circular
Multilobal
Triangular
Lobular
Triangular
Square
Polygonal
Dog bone
Lima beam

Each type of cross-section can have a smooth or serrated edge that can extend in the form of striations along the entire yarn length. Surface modification and texturing can be applied to each type of yarn to improve aesthetics, durability and other properties in a desired way.

Mixed-denier filament bundling, which combines fibers of several denier sizes in one yarn, can also be applied to the various multiyarn structures.

The ends of staples may contain the same additive or different additives. Each staple can contain multiple different additives. Continuous, single filament fluorescent yarns are co-woven or co-knitted with continuous, single filament phosphorescent and continuous, single filament. The yarns can have the same denier or possibly different denier. Phosphorescent, fluorescent and fine monofilament yarns are twisted together loosely or more tightly into a single multifilament yarn. The denier per filament (dpf) and number of filaments can be varied in compliance with the acceptable total yarn denier. Phosphorescent, fluorescent fine monofilament or multiflament yarns are twisted together loosely or more tightly into a ply yarn. The denier and number of individual yarns that form the ply yarn can be varied in compliance with the acceptable total yarn denier.

A textile, either woven or nonwoven, that can become highly transparent and render the object behind it visible to an observer when illuminated with light of specific spectral content is possible using the present invention. The same textiles become colored and no more transparent when illuminated with light having a different spectral content.

The ability to be transparent or not transparent depends on the type of illuminating light and on the type of fluorescent nanoparticles used in the textile. The absorption and emission properties of the fluorescent nanoparticles are such that light with certain wavelengths is selectively absorbed and converted to light of a different wavelength as long as the incident light wavelength is shorter than the wavelengths comprising the emission spectrum of the fluorescent particles. For example, consider a shirt made of a material containing fluorescent nanoparticles emitting green light. The green fluorescent light has a specific wavelength. The nanoparticles can absorb any light having wavelength that is shorter than the wavelength of green fluorescent light. Light with wavelengths longer than the wavelength of green is not absorbed and the material becomes effectively transparent at light at those wavelengths.

Although the present invention is illustrated and described herein with reference to preferred embodiments and specific examples thereof, it will be readily apparent to those of ordinary skill in the art that other embodiments and examples may perform similar functions and/or achieve like results. All such equivalent embodiments and examples are within the spirit and scope of the present invention, are contemplated thereby, and are intended to be covered by the following non-limiting claims.

What is claimed is:

1. A light management substrate, comprising:
a first component having a first predetermined optical property; and
a second component having a second predetermined optical property.

2. The substrate of claim 1, wherein the first component and the second component each comprise one of a fiber, a yarn, a layer, a coating, and a structural component.

3. The substrate of claim 1, wherein the first component and the second component are assembled into one of a fabric, a layer, and a planar structure.

4. The substrate of claim 1, wherein the first predetermined optical property and the second predetermined optical property each comprise one or more of a scattering property, a fluorescence property, a coherence property, a phosphorescence property, a photochromic property, a thermochromic property, and a filtering property.

5. The substrate of claim 1, wherein one or more of the first component and the second component scatter one or more of incident light and reflected light.

6. The substrate of claim 1, wherein one or more of the first component and the second component absorb one or more of incident light and reflected light and fluoresce resulting light.

7. The substrate of claim 6, wherein the resulting light is one or more of visible light, near-infrared light, and infrared light.

8. The substrate of claim 1, wherein one or more of the first component and the second component is one or more of phosphorescent, photochromic, and thermochromic.

9. The substrate of claim 1, wherein one or more of the first component and the second component are visually opaque.

10. The substrate of claim 1, wherein one or more of the first component and the second component are one or more of visually transparent, transparent to near-infrared light, and transparent to infrared light.

11. The substrate of claim 1, wherein one or more of the first component and the second component comprise a filtering material.

12. The substrate of claim 11, wherein the filtering material is disposed proximal to a structure disposed adjacent to the substrate.

13. The substrate of claim 11, wherein the filtering material is disposed distal from a structure disposed adjacent to the substrate.

14. The substrate of claim 1, wherein the first component and the second component are disposed at least in part in a spaced apart relationship across a width of the substrate.

15. The substrate of claim 1, wherein the first component and the second component are disposed at least in part in a vertical configuration across a height of the substrate.

16. The substrate of claim 1, wherein one or more of the first component and the second component act as an optical waveguide.

17. The substrate of claim 1, wherein at least one of the first component and the second component act as at least a part of a lenticular lens.

18. The substrate of claim 1, wherein a plurality of gaps are formed between the first component and the second component, and wherein one or more of the first component and the second component scatter, fluoresce, or emit resulting light such that the plurality of gaps are rendered visually opaque.

19. The substrate of claim 1, wherein the first component scatters, fluoresces, or emits resulting light of a predetermined wavelength and the second component scatters or absorbs the resulting light of the predetermined wavelength, thereby manipulating one or more of incident light and reflected light in a cascaded manner.

20. The substrate of claim 1, wherein one or more of the first component and the second component fluoresce or emit resulting light of a predetermined wavelength.

21. The substrate of claim 20, wherein the predetermined wavelength comprises a long infrared wavelength greater than about 700 nm.

22. The substrate of claim 1, wherein one or more of the first component and the second component comprise a plurality of microspheres operable for scattering one or more of incident light and reflected light.

23. The substrate of claim 1, wherein the first component and the second component are disposed adjacent to a photovoltaic device such that light of a predetermined wavelength is directed from the substrate to the photovoltaic device.

24. The substrate of claim 1, wherein one or more the first component and the second component are thermochromic and both are disposed adjacent to a user device such that the substrate is selectively rendered at least partially transparent and the user device is made visible to a user.

25. A light management substrate, comprising:
a first component having a first predetermined optical property; and
a second component having a second predetermined optical property;
wherein the first component and the second component each comprise one of a fiber, a yarn, a layer, a coating, and a structural component;
wherein the first component and the second component are assembled into one of a fabric, a layer, and a planar structure; and
wherein the first predetermined optical property and the second predetermined optical property each comprise one or more of a scattering property, a fluorescence property, a coherence property, a phosphorescence property, a photochromic property, a thermochromic property, and a filtering property.

26. The substrate of claim 25, wherein one or more of the first component and the second component scatter incident light.

27. The substrate of claim 25, wherein one or more of the first component and the second component absorb incident light and fluoresce resulting light.

28. The substrate of claim 27, wherein the resulting light is one or more of visible light, near-infrared light, and infrared light.

29. The substrate of claim 25, wherein one or more of the first component and the second component is one or more of phosphorescent, photochromic, and thermochromic.
